(19) United States
(12) Patent Application Publication
(10) Pub. No.: US 2024/0169245 A1
(43) Pub. Date: May 23, 2024

(54) QUANTUM RANDOM NUMBER GENERATOR

(71) Applicants: Quantum Silicon Inc., Edmonton (CA); The Governors of the University of Alberta, Edmonton (CA)

(72) Inventors: Robert A. Wolkow, Edmonton (CA); Roshan Achal, Edmonton (CA); Lucian Livadaru, Edmonton (CA)

(73) Assignees: Quantum Silicon Inc., Edmonton, AB (CA); The Governors of the University of Alberta, Edmonton, AB (CA)

(21) Appl. No.: 18/282,631

(22) PCT Filed: Mar. 18, 2022
(86) PCT No.: PCT/CA2022/050410

§ 371 Date: Sep. 18, 2023

Related U.S. Application Data
(60) Provisional application No. 63/163,182, filed on Mar. 19, 2021.

(51) Int. Cl. G06N 10/60; G06F 7/58

(52) U.S. Cl. CPC G06N 10/60; G06F 7/58

(57) ABSTRACT

A quantum random number generator (QRNG) that includes at least one potential well and an electron detector outputting unique signals for quantized electron occupations as a source of random numbers. The at least one potential well including at least one exactingly placed dangling bond (DB) that is biased via a control wire. The DB extends from a silicon atom or from a germanium atom. Additionally, a method of operating the quantum random number generator includes measuring the unique signals as low/high current values or times between output transitions to assign maximal and minimal values leading to a constant stream of the source of random numbers.

### CROSS REFERENCE TO RELATED APPLICATIONS

This application claims priority benefit of U.S. Provisional Application Ser. No. 63/163,182 filed 19 Mar. 2021, the contents of which are hereby incorporated by reference.

### FIELD OF THE INVENTION

The present invention in general relates to atomic structures, and in particular to an ultra-low power, high speed hardware random number generator.

### BACKGROUND OF THE INVENTION

True random number generating devices are employed in many applications related to secure communications and probabilistic computing. While adequate for many markets, the devices available today are unable to satisfy portable applications that require substantially reduced size, weight, and power. Excessive power consumption is the dominant issue preventing mobile, battery operated applications. The chip-sized true random number generator made by ID Quantique SA, for example, represents the cutting edge in small portable devices. It has a continuous power consumption of about 100 milliwatts. A quantum random number generator (QRNG) with at least an order of magnitude lower power consumption would enable further deployment in mobile computing and security applications. In addition to the low power requirements of portable applications, there are many applications where heat dissipation, not power consumption, is limited. Those applications also require a hardware QRNG of far lower power consumption than any now in existence.

U.S. Pat. No. 10,937,959 of Applicant, and incorporated herein in its entirety, describes the use of multiple dangling bonds (DBs) on an otherwise H-terminated silicon surface that form quantum dots to provide devices based on the modulation of the occupation state of a DB on such a quantum dot. As disclosed therein, a multiple-atom silicon quantum dot is provided that includes multiple dangling bonds on an otherwise H-terminated silicon surface, each dangling bonds having one of three ionization states of +1, 0 or −1 and corresponding respectively to 0, 1, or 2 electrons in a dangling bond state. The dangling bonds together in close proximity and having the dangling bond states energetically in the silicon-, germanium-, or carbon-band gap with selective control of the ionization state of one of the dangling bonds. A new class of electronics elements is provided through the inclusion of at least one input and at least one output to the multiple dangling bonds. Selective modification or creation of a dangling bond is also detailed.

While there have been many advances in atomic structures, there exists a need for improved true random number generating devices for portable applications that require substantially reduced size, weight, and power. There is a further need to implement true random number generating devices using quantum mechanics.

### SUMMARY OF THE INVENTION

The present invention provides a quantum random number generator (QRNG) that includes at least one potential well and an electron detector outputting unique signals for quantized electron occupations as a source of random numbers. The at least one potential well including at least one exactingly placed dangling bond (DB) that is biased via a control wire. The DB extends from a silicon atom, a germanium atom, or a carbon atom. The present invention additionally provides a method of operating the quantum random number generator that includes measuring the unique signals as low/high current values or times between output transitions to assign maximal and minimal values leading to a constant stream of the source of random numbers.

### BRIEF DESCRIPTION OF THE DRAWINGS

The subject matter that is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIGS. 1A and 1B illustrate an exactingly placed silicon dangling bonds (DBs), with an electron that is allowed to randomly hop between a left (L) and right (R) side, where in FIG. 1A the electron is shown localized on the left side, while in FIG. 1B the electron has moved to the right side by quantum mechanically tunneling through the barrier separating the two minima;

FIG. 1C is a plot of two measurements of electron position of an exactingly placed silicon dangling bond, where the dark trace shows the electron on the left side; the lighter trace, after tunneling, on the right side;

FIG. 2 is a “strip chart” record of many subsequent readings of electron position of FIGS. 1A and 1B;

FIG. 3 illustrates an atom-defined single electron transistor (SET);

FIG. 4 illustrates a quantum random number generator (QRNG) in accordance with embodiments of the invention;

FIG. 5A illustrates a QRNG having a single potential well in accordance with embodiments of the invention with an exactingly placed DB with an electron localized on the right side;

FIG. 5B illustrates the QRNG of FIG. 5A with an exactingly placed DB with an electron localized on the left side;

FIG. 6 illustrates a radio frequency electron detector of a QRNG in accordance with embodiments of the invention;

FIG. 7 illustrates a three dangling bond potential well in accordance with embodiments of the invention;

FIG. 8 illustrates a four dangling bond potential well in accordance with embodiments of the invention;

FIG. 9 illustrates a potential well of a plurality of dangling bonds in accordance with embodiments of the invention;

FIG. 10 illustrates a QRNG having four potential wells and two electron detectors operating in parallel;

FIG. 11A illustrates a QRNG having a pair of electrodes bounding the potential well in accordance with embodiments of the invention with an exactingly placed DB with an electron localized on the left side;

FIG. 11B illustrates the QRNG of FIG. 11A with an electron localized on the right side;

FIG. 12 illustrates a QRNG having a central electrode between two potential wells in accordance with embodiments of the invention;

FIG. 13A illustrates a QRNG in which an electric field is used to set an initial electron positional state in accordance with embodiments of the invention;

FIG. 13B illustrates the QRNG of FIG. 13A with the electric field is turned off to measure the quantized electron occupation;

FIGS. 14A and 14B illustrate a QRNG in which an electric field is used to extract an electron from the potential well in accordance with embodiments of the invention;

FIG. 15A illustrates a QRNG in which an electrode is used to reset electron position in two dangling bond pairs at t=0; and

FIG. 15B illustrates a QRNG of FIG. 15A in which the electrode is off and t>tunneling half-life, so the electron in each pair will randomly be in one of the two wells causing the output of the XOR gate to randomly be 0 or 1.

### DETAILED DESCRIPTION OF THE INVENTION

The present invention has utility as a quantum random number generator (QRNG). A method is provided for reproducible fabrication of atom-defined silicon structures, in an exacting fashion, that are entirely stable and unchanging at and well above room temperature. These fixed atomic silicon-, germanium-, or carbon-structures localize single electrons while also isolating the single electrons from the bulk electronic states that are employed in conventional semiconductor electronic devices. Though confined, each electron is free to occupy two or more local minima. Interactions among the individual multi-stable electrons allow for a range of both passive and active electronic components to be defined. Locally applied potential controls can direct interactions among electrons so as to achieve computation and information transmission. Alternatively, conditions can be established that enable the electronic state of a device to quantum mechanically evolve randomly among degenerate configurations. Adjacent atom-specific electrical measurements can readily detect and discriminate among such evolving electronic states to provide a readout device. Moreover, atom-defined wires can serve to dynamically bias a double well potential so as to deterministically localize the single electron to one or the other of the composite single atom states, or to symmetrize the well thereby enabling free electron evolution. As described in “Detecting and Directing Single Molecule Binding Events on H—Si(100) with Application to Ultradense Data Storage”, (Achal et al., ACS Nano, 2019), and included herein in its entirety, a versatile scanning tunneling microscope (STM) charge characterization technique is provided, which reduces the influence of the typically perturbative STM tip field. Using this technique, single molecule binding events can now be observed to atomically define reactive sites (fabricated on a hydrogen-terminated silicon surface) through electronic detection. A simplified error correction tool is also provided for automated hydrogen lithography, quickly directing molecular hydrogen binding events using these sites to precisely repassivate surface dangling bonds (without the use of a scanned probe). As described in “Initiating and Monitoring the Evolution of Single Electrons Within Atom-Defined Structures”, (Rashidi et al., American Physical Society, 2018), and included herein in its entirety, a method is provided for using a noncontact atomic force microscope to track and manipulate the position of single electrons confined to atomic structures engineered from silicon-, germanium-, or carbon-dangling bonds on the hydrogen terminated respective surface.

In the context of the present invention, carbon surfaces are intended to have sp² hybridization while DBs extending therefrom are a hybrid of sp² and sp³.

Embodiments of the inventive QRNG are based upon Applicant's atomic quantum dots as disclosed in WO2009153669, WO2018015809, WO2019060999, and are included herein in their entirety. Applicant's Field Controlled Computing Technology is based on the ability to create and position atomic quantum dots on a silicon-, germanium-, or carbon-surface. For many years, automated and scalable atom-scale manufacturing processes evaded developers around the world. Applicant's technology provides both the unique tools and the physical processes that allow error-free, automated and scalable atomically precise manufacturing. As described in “SIQAD: A Design and Simulation Tool for Atomic Silicon Quantum Dot Circuits”, (Ng et al., arXiv:1808.04916v1 [cond-mat.mes-hall] 14 Aug. 2018), and included herein in its entirety, introduces SiQAD, a computer-aided design tool enabling the rapid design and simulation of atomic silicon dangling bond quantum dot patterns capable of computational logic. Applicant's unique capabilities derive from our world leading atom-perfect silicon lithography. These processes work on ordinary silicon-, germanium-, or carbon-substrates and are CMOS compatible. Applicant's atom-defined patterning techniques provide access to electronic properties of silicon, germanium, or carbon that are beyond the reach of conventional transistor technology.

It is to be understood that in instances where a range of values are provided that the range is intended to encompass not only the end point values of the range but also intermediate values of the range as explicitly being included within the range and varying by the last significant figure of the range. By way of example, a recited range of from 1 to 4 is intended to include 1-2, 1-3, 2-4, 3-4, and 1-4.

The atom defined structures are small, but the structures are not fragile. Unlike early exploratory atom-scale structures that persisted only at extreme cryogenic conditions, embodiments of the inventive devices are entirely stable to 500 degrees Kelvin. The bonds holding patterned atoms in place are of a strength comparable to those within granite rendering the devices impervious to vibration. Secure encapsulation renders the devices immune to dust and airborne contaminants. This results in quantum mechanical tunneling and single electron control with ultra-low power consumption and unprecedented high bandwidth. The atomic quantum dots used in embodiments of the invention are created by removing individual hydrogen atoms from hydrogen-terminated silicon, germanium, or carbon.

As used herein, a hydrogen-terminated is intend to also include isotopes of deuterium and tritium.

Not to be limited to a specific theory, embodiments of the inventive QRNG rely on the fundamentally random duration of dwell times exhibited by a single electron as it quantum mechanically tunnels through the barrier of at least one potential well and in other embodiments two or more such potential wells in form of dangling bonds. The changing position of the tunneling electron triggers an adjacent atom-defined single electron transistor to switch between two distinct conductive states. The two-state telegraph-like signal emerging from the single electron transistor is large enough to be read by ordinary transistor circuitry that interfaces with the QRNG that serves as a true random number generator (TRNG). In a single potential well embodiment of the present invention, the surrounding occupied orbitals on the surface acts as a quantum barrier and the with application of an applied voltage, the dangling bond perturbation response is measured as a source of random numbers.

The inventive ability to dynamically bias a double well potential so as to deterministically localize the single electron to one or the other of the composite single atom states, or to symmetrize free electron evolution has been employed to produce a quantum random number generator (QRNG). Specific embodiments of the inventive QRNG employ a double well potential consisting of a pair of exactingly placed silicon-, germanium-, or carbon-dangling bonds (DBs) that are biased via a control wire (dangling bond wire interfacing with a macro connection). While the instances of two or more coupled potential wells are generally detailed herein as being like atoms, it is appreciated that heterogenous wells are readily used in the present invention. Two potential well pairs therefore include Si—Si, Ge—Ge, C—C, Si—Ge, Si—C, and Ge—C DBs. The bias serves to push the electron to one side of the DB pair as a “starting position”. The bias can also be used to tune a random bit output to achieve a range of desired statistical distributions.

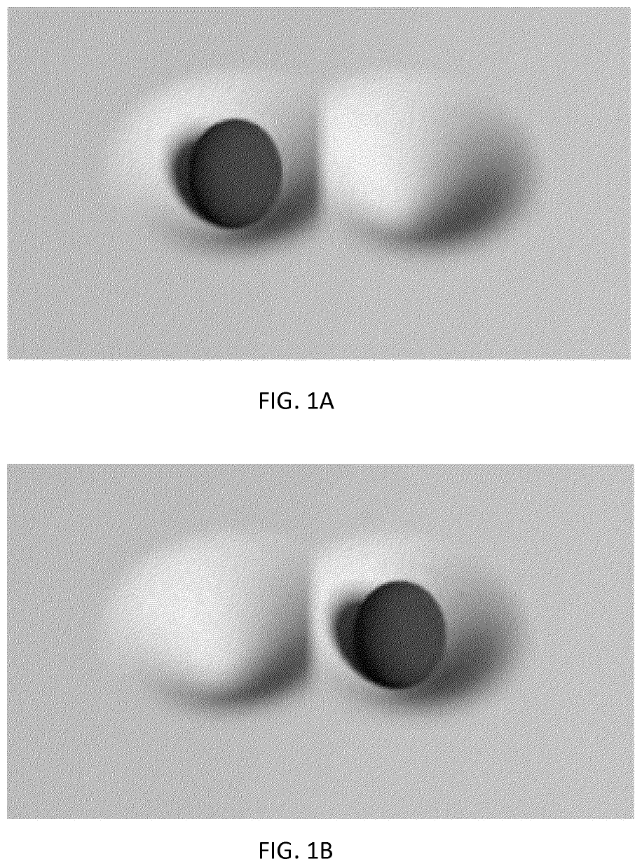

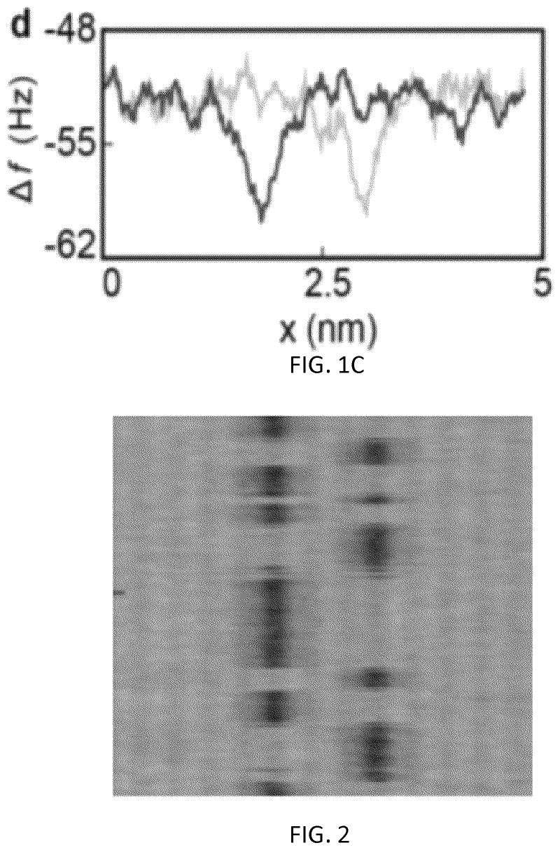

In a specific inventive embodiment of an exactingly placed silicon-, germanium-, or carbon-dangling bonds (DBs), an electron is allowed to randomly hop between a left (L) and right (R) side. As shown in FIGS. 1A and 1B a double well potential energy surface is occupied by single electron. In FIG. 1A the electron is shown localized on the left side, while in FIG. 1B the electron has moved to the right side by quantum mechanically tunneling through the barrier separating the two minima. The double well is composed of two silicon atoms, two germanium atoms, two carbon atoms, or a combination thereof. Because the atoms are positioned on the perfectly regular lattice sites of a crystalline silicon substrate, there can be no variance in device dimensions. Furthermore, because the electronic states associated with the patterned surface atoms lie in the band gap of the correspond bulk material, the atom-defined structures are effectively electronically isolated from the surface to which they are firmly bonded. It is noted that quantum coherence is not required or called upon in this application. FIG. 1C is a plot of two measurements of electron position of an exactingly placed silicon dangling bond, where the dark trace shows the electron on the left side; the lighter trace, after tunneling, on the right side. FIG. 2 is a “strip chart” record of many subsequent readings of electron position of FIGS. 1A and 1B. Analysis of such data streams straightforwardly reveals a true quantum random number stream of binary data.

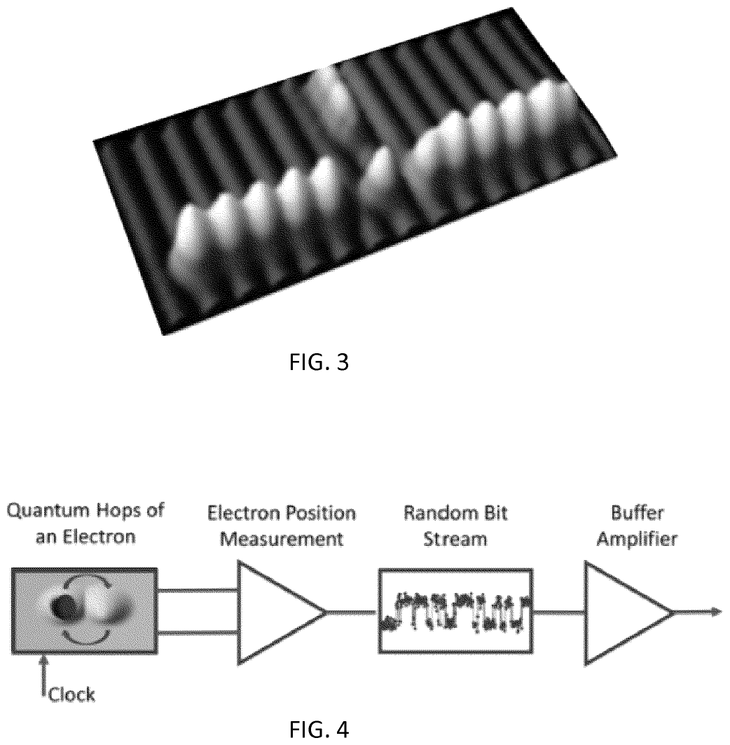

The change in electron position of FIGS. 1A and 1B is detected by a nearby single electron transistor (SET). R. H. Chen et al. Appl. Phys. Lett. 68 (14), 1 Apr. 1996, 1954-1956. FIG. 3 illustrates an atom-defined single electron transistor (SET). The SET device senses the position of the electron, where the three leads can be thought of as source, gate and drain in analogy to a field effect transistor (FET). Unlike an FET, the current through the SET device cannot be continuously varied by a variable gate potential. The SET abruptly jumps between quantized current magnitudes. The magnitude of the jumps in current change becomes larger if the central quantum dot can be made smaller. Because of the ultimate small quantum dot of the present invention, the largest and easiest-to-detect current changes are achieved. This translates to optimal sensitivity and ability to work at elevated temperatures, unlike other SETs. The SET transduces a tiny change in electron position to a change in output current.

The SET serves as a binary electron detector outputting only two current levels, one corresponding to each of the two electron positions in the double well potential. The output currents that are in the range of femtoamps to milliamps are sufficient to drive conventional transistor interface circuitry. The use of an external amplifier may also be included to increase the output level. The low/high current values obtained, or the times between output transitions can be assigned a 0/1 binary representation, leading to a constant stream of random binary numbers depending on the dwell time of the electron.

In still other inventive embodiments, the electron detector is radio-frequency (RF) reflectometer. The application of reflectometry to quantum systems is known. A. Crippa et al. Nano Lett. 2017, 17, 2, 1001-1006.

In a specific inventive embodiment, the DB pair is periodically biased via a clocking wire at a fixed rate to “prepare” the electron on a known side of the DB pair. Upon release of the bias, the electron is free to evolve in accord with quantum tunneling statistics. The SET is used to detect the electron position with fast time resolution, returning a low or high signal based on the electron position.

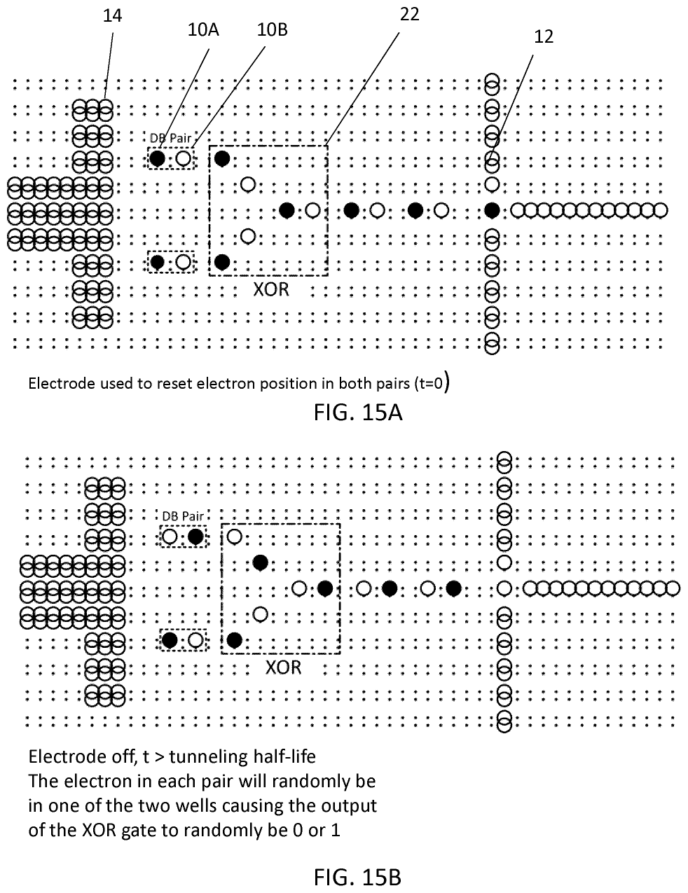

In a further inventive embodiment, two biasable DB pairs serve as independent random inputs into an output debiasing circuit built from DB gates (an XOR gate or other gate type). An XOR gate 22 formed of DBs is depicted in FIGS. 15A and 15B. The construction and operation of DB gate structures is further detailed in U.S. Pat. No. 10,937,959. As a result, the source of random numbers used in the present invention can be debiased. These atom-defined gates can operate at rates approaching 1 THz. The output of this circuit is detected by a nearby atom-defined SET. The change in gate output causes a low/high or high/low current output from the SET. An on-chip debiasing circuit helps ensure a flat distribution of 0s and 1s. The atom-defined gate operation rate correlates with the random generation number rate with the appreciation that the tunneling speed is faster than the clock rate.

In addition to a SET detection scheme, in specific inventive embodiments an RF-reflectometry setup is used to measure the random position of the electron in a DB pair. This implementation requires an external peripheral circuitry that is capable of performing this RF measurement.

It is noted that the basis for input and output are inventive macro-to-atom connections developed by Applicant for general DB circuitry. Embodiments of the inventive input and output device may be packaged as a standalone chip that can be incorporated directly into any number of applications where a small portable true random number generator (TRNG) is required. Alternatively, the atom defined circuitry can be fabricated directly onto the same die of an otherwise conventional silicon integrated circuit. Additional bit streams could be generated by integrating multiple chips, or by increasing the number of independent DB pairs and SETs on a single chip. In an inventive embodiment a CMOS chip fabricated using conventional photolithographic techniques is connected to the atomic scale features of the inventive QRNG. The resulting chip may be encapsulated in conventional semiconductor packaging for routine handling, signal readout, printed circuit board placement, and use.

Embodiments of the inventive QRNG only draw microwatts of power, are extremely small and light weight, and meet rigorous temperature and vibration requirements that are experienced in mobile applications. These qualities plus gigabit per second data rates are made possible by the quantum properties of Applicant's atomic quantum dot technologies.

In the following FIGURES, a filled (dark) circle denotes electron fill of a potential well, while an unfilled circle denotes an unfilled potential well. Deposition of other materials to form wires, electrodes, or detector components are denoted as overlapping circles. The background of pattern denotes hydrogen passivated atoms of the surface and depict monoatomic substances. Like features are not labelled in the second of a pair of FIGURES for visual clarity. “E” with an associated arrow denotes a biasing potential direction. Like reference numerals in subsequently details FIGURES are intended to have the meaning ascribed thereto with respect to the aforementioned details of that aspect.

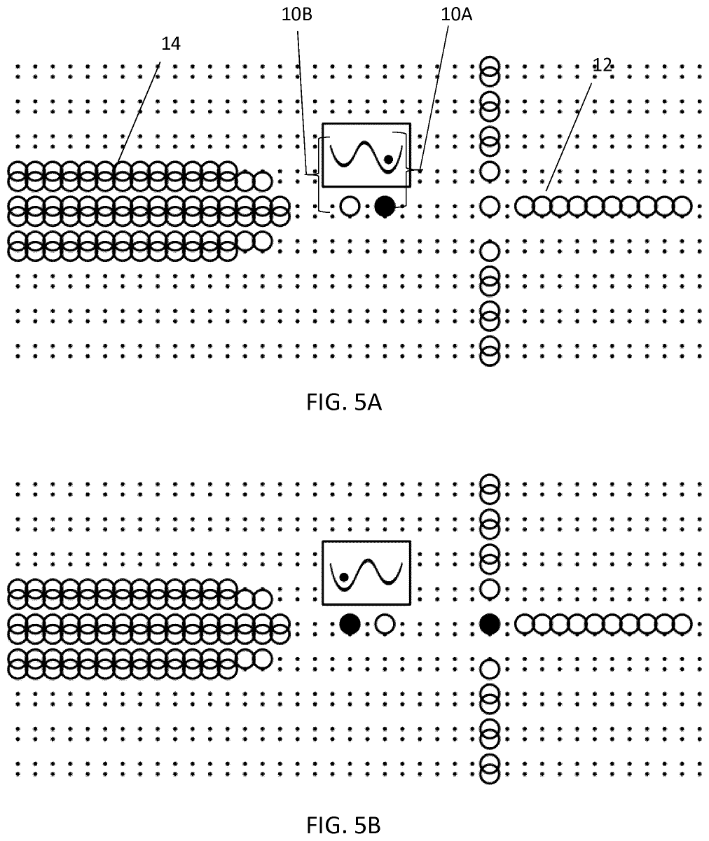

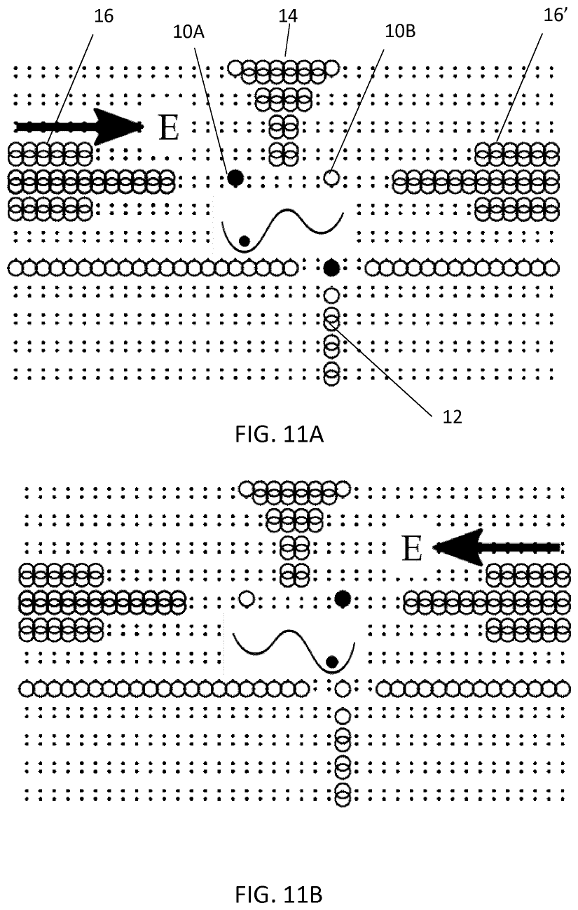

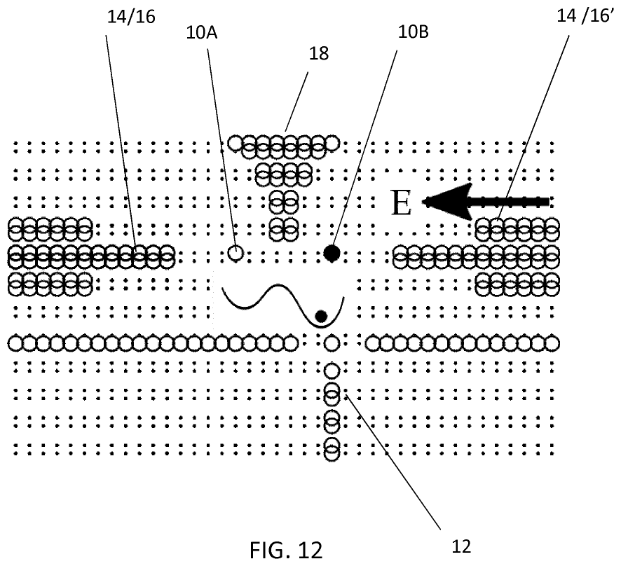

According to some inventive embodiments, such as that shown in FIGS. 5A and 5B, a QRNG is provided with two potential wells 10A, 10B that are defined on exactingly placed dangling bonds (DBs) that is biased via a control wire 14, and an electron detector 12 outputting unique signals for quantized electron occupations as a source of random numbers. It should be appreciated that the potential well energy as a function of distance schematics of FIGS. 15A and 15B are a mere depiction for visual clarity and is not present separate from the dangling bonds. This is also the case for FIGS. 11A, 11B, 12A, 12B, 13A, 13B, 14A, and 14B. According to some inventive embodiments, the QRNG additionally includes an amplifier (not shown) that is in electronic communication with an inventive electron detector to perform electrical signal enhancement. As will be further detailed herein, an inventive electron detector functions through current detection or reflectometry. As a result, according to some inventive embodiments, the unique signals are only current levels associated with electron tunneling from a potential well in the form of a DB or a collection of DBs. According to embodiments, the electron detector 12, regardless of whether SET or reflectometer, and the DB operates at a temperature between 0 and 500 degrees Kelvin. According to embodiments, the DB of the QRNG extends from a silicon, germanium, or carbon atom. According to embodiments, the QRNG additionally includes a pair of electrodes 16, 16′ bounding the at least one potential well, as shown in FIGS. 11A and 11B. According to embodiments, the QRNG additionally includes a central electrode 18 between two potential wells, as shown in FIG. 12.

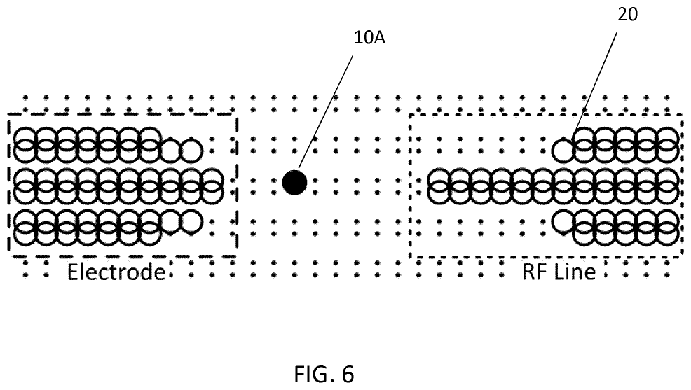

According to some inventive embodiments, the electron detector 12 is a radiofrequency (RF) reflectometer line 20, as shown in FIG. 6. In FIG. 6, a single DB 10B is shown that can be biased by the electrode 16. According to other inventive embodiments, the electron detector 12 of the QRNG is an atom-defined single electron transistor (SET) in which the SET output signals are currents that correspond to a change in electron position in the DB. The SET currents range from femtoamps to milliamps. The currents operate transistor interface circuitry that is synonymously referred to herein as CMOS circuitry. CMOS circuitry operative herein is detailed with greater specificity in WO2019014753A1.

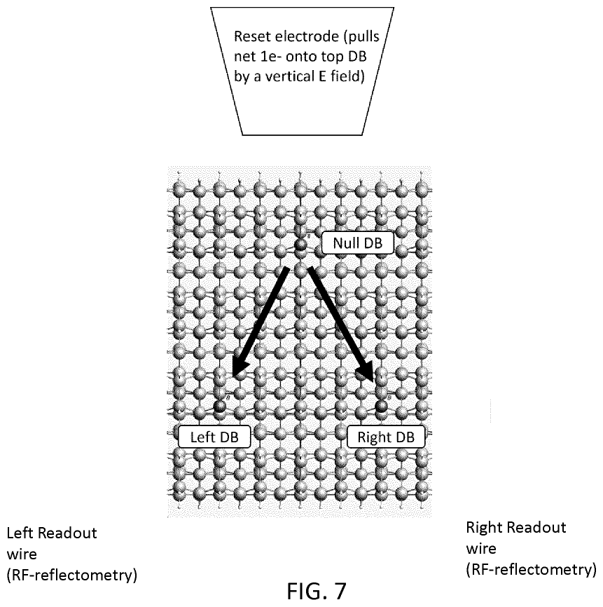

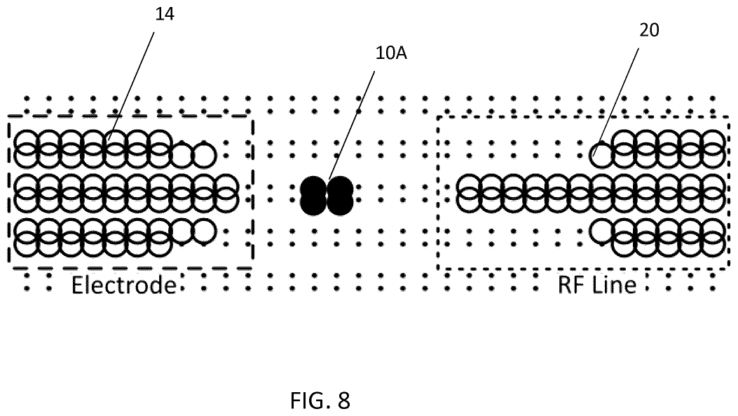

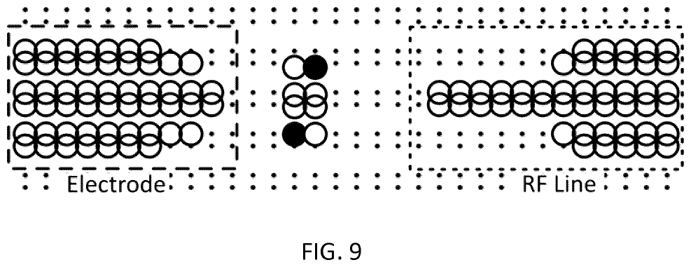

According to other inventive embodiments, the at least one potential well 10A is a plurality of dangling bonds and is eight DBs as shown in FIG. 9. It should be appreciated that each DB independently has a charge of +1, 0, −1 regardless of the number of DBs that are the source of the random numbers generated according to the present invention. According to embodiments, the at least one potential well 10A is three dangling bonds that define a triangle, line, or an angle, as shown in FIG. 7. According to embodiments, the at least one potential well 10A is four dangling bonds that define a square, a rectangle, a line, or an angle, as shown in FIG. 8.

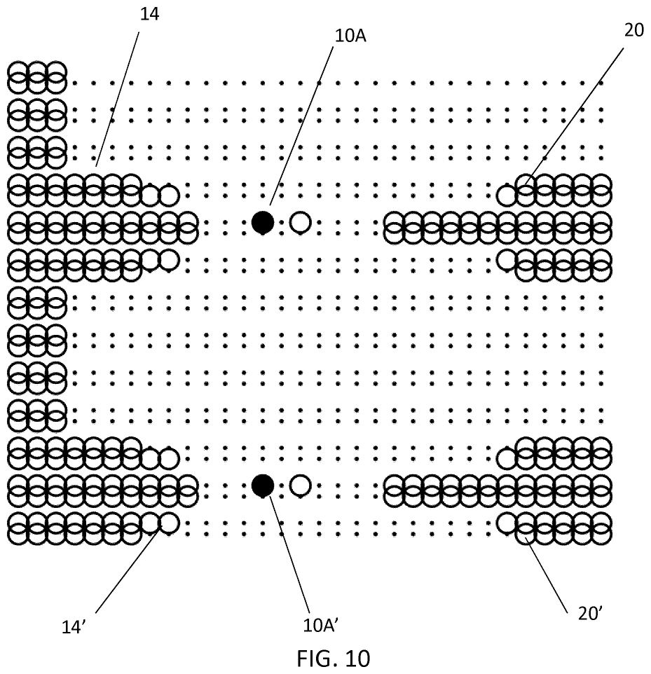

According to embodiments, such as that shown in FIG. 10, the QRNG additionally includes a second potential well that includes an exactingly paced dangling bond that is biased via a control wire and a second electron detector outputting unique signals for quantized electron occupations as a source of random numbers, the second electron detector operating in parallel to an in proximity to the electron detector with components thereof denoted with primes (′) relative to those of FIG. 6.

According to embodiments, a method of operating a QRNG is also provided. The method includes measuring the unique signals as low/high current values or times between output transitions to assign maximal and minimal values leading to a constant stream of the source of random numbers. According to embodiments, the maximal and minimum values define a binary source of random numbers or the maximal and minimum values define a ternary source of random numbers and the at least one potential well comprises at least two DBs.

According to embodiments, the method additionally includes injecting a hole locally relative to the at least one DB to deplete an electron, measuring a time for electron replenishment as the source of random numbers, and/or distorting the at least one potential well with the application of an electric field to control the quantized electron occupation. According to embodiments, the electric field is transient relative to the measuring.

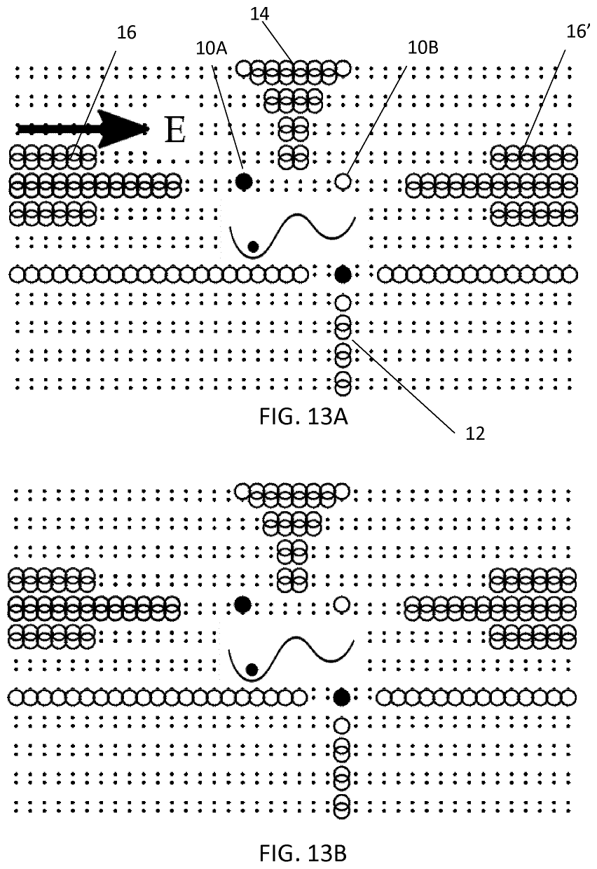

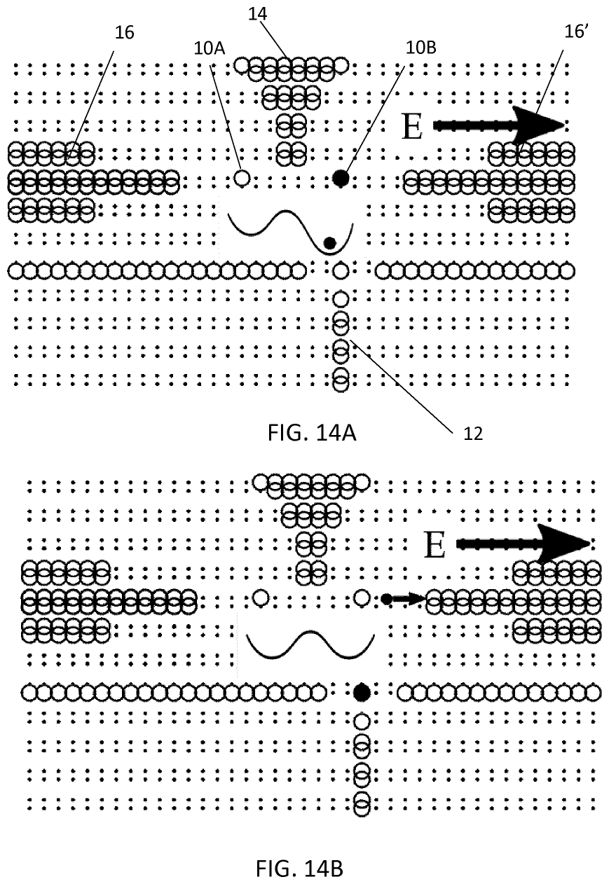

According to embodiments the method additionally includes setting an initial electron positional state via an electric field then turning off the electric field to measure the quantized electron occupation (as shown in FIGS. 13A and 13B), energizing a central electrode 14 intermediate between two potential wells 10, 10B, and/or extracting at least one electron from the potential wells (as shown in FIGS. 14A and 14B).

Any patents or publications mentioned in this specification are herein incorporated by reference to the same extent as if each individual publication was specifically and individually indicated to be incorporated by reference.

The foregoing description is illustrative of particular embodiments of the invention but is not meant to be a limitation upon the practice thereof.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the described embodiments in any way. Rather, the foregoing detailed description will provide those skilled in the art with a convenient road map for implementing the exemplary embodiment or exemplary embodiments. It should be understood that various changes can be made in the function and arrangement of elements without departing from the scope as set forth in the appended claims and the legal equivalents thereof.

1. A quantum random number generator (QRNG) comprising:
at least one potential well comprising at least one exactingly placed dangling bond (DB) that is biased via a control wire; and
an electron detector outputting unique signals for quantized electron occupations as a source of random numbers.

2. The quantum random number generator of claim 1 wherein the unique signals are only current levels.

3. The quantum random number generator of claim 1 further comprising an amplifier.

4. The quantum random number generator of claim 1 wherein the electron detector is an atom-defined single electron transistor (SET).

5. The quantum random number generator of claim 4 wherein the SET output signals are currents that correspond to a change in electron position in the DB.

6. (canceled)

7. The quantum random number generator of claim 5 wherein the currents operate CMOS circuitry.

8. The quantum random number generator of claim 1 wherein the electron detector is radio-frequency (RF) reflectometer.

9. The quantum random number generator of claim 1 wherein the electron detector and the DB operates at a temperature between 0 and 500 degrees Kelvin.

10. The quantum random number generator of claim 1 wherein the DB extends from a silicon atom, a germanium atom, or a carbon atom.

11. (canceled)

12. The quantum random number generator of claim 1 wherein the at least one potential well is two potential wells, three potential wells defining a triangle, line, or an angle; four potential wells defining a square, a rectangle, line; an angle; or plurality of DBs.

13. (canceled)

14. (canceled)

15. (canceled)

16. The quantum random number generator of claim 1 wherein the source of random numbers is debiased.

17. The quantum random number generator of claim 16 wherein the debiasing is created by dangling bond circuitry.

18. (canceled)

19. The quantum random number generator of claim 1 further comprising a second one potential well comprising an exactingly placed dangling bond (DB) that is biased via a control wire; and
a second electron detector outputting unique signals for quantized electron occupations as a source of random numbers, the second electron detector operating in parallel to and in proximity to the electron detector.

20. The quantum random number generator of claim 1 further comprising a pair of electrodes bounding the at least one potential well a central electrode between two potential wells of the at least one potential well, or a combination thereof.

21. (canceled)

22. A method of operating the quantum random number generator of claim 1 comprising:
measuring the unique signals as low/high current values or times between output transitions to assign maximal and minimal values leading to a constant stream of the source of random numbers.

23. The method of claim 22 wherein the maximal and minimum values define a binary source of random numbers or a ternary source of random numbers and the at least one potential well comprises at least two DBs.

24. (canceled)

25. The method of claim 22 further comprising distorting the at least one potential well with the application of an electric field to control the quantized electron occupation.

26. (canceled)

27. The method of claim 22 further comprising setting an initial electron positional state via an electric field then turning off the electric field to measure the quantized electron occupation.

28. The method of claim 22 further comprising energizing a central electrode intermediate between two potential wells of the at least one potential well.

29. The method of claim 22 further comprising extracting at least one electron from the at least one potential well.
